(19) United States
(12) Patent Application Publication
(10) Pub. No.: US 2026/0267236 A1
(43) Pub. Date: Sep. 10, 2026

(54) Overlay Measurement Device, Focus Control Method of Overlay Measurement Device for Tool-induced Shift Measurement, and Focus Control Program of Overlay Measurement Device for Tool-induced Shift Measurement

(71) Applicant: AUROS TECHNOLOGY, INC., Hwaseong-si (KR)

(72) Inventors: Soo Yeon MO, Hwaseong-si (KR); Jung Sun KO, Hwaseong-si (KR); Seong Yun CHOI, Hwaseong-si (KR); Suk Hyun AHN, Hwaseong-si (KR)

(21) Appl. No.: 19/577,273

(22) Filed: Mar. 24, 2026

Related U.S. Application Data
(63) Continuation of application No. PCT/KR2024/011016, filed on Jul. 29, 2024.

(30) Foreign Application Priority Data
Sep. 25, 2023 (KR) 10-2023-0127833

(51) Int. Cl. G03F 7/00

(52) U.S. Cl. CPC G03F 7/70633; G03F 7/70641; G03F 7/706849

(57) ABSTRACT

Proposed is a focus control method of an overlay measurement device for tool-induced shift measurement. With the proposed method, distortion of tool-induced shift that occurs when an area illuminated by illumination used in the auto-focus device exceeds a size of an overlay mark can be reduced, and thus a more accurate tool-induced shift value can be obtained. Further, by correcting an overlay error using such a tool-induced shift value, an overlay error can be measured more accurately even on a wafer on which small-sized overlay marks are formed.

### TECHNICAL FIELD

The present disclosure relates to an overlay measurement device, a focus control method of an overlay measurement device for tool-induced shift measurement, and a focus control program of an overlay measurement device for tool-induced shift measurement.

### BACKGROUND ART

A plurality of pattern layers is sequentially formed on a semiconductor substrate. In addition, a circuit of one layer may be formed in two patterns through double patterning. Such pattern layers or a plurality of patterns of one layer needs to be formed accurately at preset positions so as to manufacture a desired semiconductor device.

Therefore, to check whether pattern layers are accurately aligned, overlay marks formed simultaneously with the pattern layers are used.

A method of measuring overlay by using an overlay mark is as follows. First, in a pattern layer formed in the previous process, for example, an etching process, one structure that is a part of the overlay mark is formed simultaneously with the formation of the pattern layer. Then, in the subsequent process, for example, a photolithography process, the remaining structure of the overlay mark is formed on the photoresist.

Next, an overlay measurement device acquires an image of the overlay structure (acquires the image with penetration through the photoresist layer) of the pattern layer formed in the previous process and an image of the overlay structure of the photoresist layer, and measures an offset value between the centers of the images to measure an overlay error value.

More specifically, JP 2020-112807 A discloses a method in which an image of an overlay mark formed on a substrate is captured, a plurality of working zones is selected from the captured image, a signal having information for each of the selected working zones is formed, and the signals are compared to determine relative shift between different layers or different patterns.

FIG. 1 is a plan view of an example of an overlay mark. The overlay mark 1 shown in FIG. 1 includes four sets of working zones 4, 5, 6, and 7. Each of the sets of working zones 4, 5, 6, and 7 includes two working zones positioned in a diagonal line. Each of the sets of working zones 4, 5, 6, and 7 is used for overlay error measurement in the direction of the X-axis or Y-axis of the pattern layer that is formed together with the corresponding set of working zones. In order to prevent an interference phenomenon, structures 2 formed with a first pattern layer and structures 3 formed with a second pattern layer are disposed so as not to overlap each other.

Each working zone includes bars that are disposed at regular intervals starting from the center of the overlay mark 1 to the outer edge of the overlay mark 1. Accordingly, using the overlay measurement device, a periodic signal may be obtained from each of the two working zones belonging to each of the sets of working zones 4, 5, 6, and 7, as shown in FIG. 2. The graph of FIG. 2 may be obtained from a selected partial area 8 shown in FIG. 1, for example.

In the graph of FIG. 2, the peaks are positioned at which the bars are disposed. Since the bars are periodically disposed in the conventional overlay mark 1, the obtained signals also have periodicity. In addition, an overlay error is measured through correlation analysis of two periodic signals obtained from two selected areas 8 and 8′.

Such overlay error measurement requires a high-quality overlay measurement device to satisfy the requirements of an enhanced lithography process. During overlay error measurement, defects (for example, aberrations) in optical elements constituting an overlay measurement device may cause tool-induced shift (TIS). Optical defects of such an overlay measurement device may cause a shift between an actual overlay error and a measured overlay error.

Tool-induced shift measurement requires repeated overlay error measurements in an unrotated state and a 180-degree rotated state of a wafer. The tool-induced shift may be a value obtained by dividing a sum of an overlay error value in an unrotated state of a wafer and an overlay error value in a 180-degree rotated state by 2. Ideally, since an overlay error value in the unrotated state and an overlay error value in a 180-degree rotated state have the same magnitude and opposite signs, the tool-induced shift is 0.

* Overlay error measurement for tool-induced shift measurement is performed at a plurality of sites (overlay marks) within a reference field.

FIG. 3 is a view illustrating an example of a wafer. As shown in FIG. 3, a semiconductor wafer includes a plurality of fields (Fs). In one field (F), a plurality of sites S1, S2, S3, and S4 exists (four sites in FIG. 3). At each of the sites S1, S2, S3, and S4, one overlay mark is positioned. A reference field is typically disposed at a center portion of a wafer. Sites having the same position within each field (F) are assigned the same site index. That is, sites that overlap when fields (Fs) are superimposed have the same site index. Measurement sites S1, S2, S3, and S4 of the semiconductor wafer shown in FIG. 3 may have site indexes from 1 to 4.

To perform overlay error measurement for tool-induced shift measurement, an image of an overlay mark needs to be obtained. In order to obtain an image of an overlay mark, a ‘measurement focus’ of the corresponding site needs to be found. The ‘measurement focus’ is a focus for obtaining an optimal image of the overlay mark, and may differ from a ‘standard focus’ found by using an auto-focus device. Finding the ‘measurement focus’ takes a relatively long time. Therefore, a method is used in which a ‘reference signal value’, which is a signal value from the auto-focus device in a state of the ‘standard focus’, is acquired in advance, and then an image of the overlay mark is acquired after adjusting a position of an objective lens so that a signal value from the auto-focus device matches the ‘reference signal value’.

In the related art, a ‘reference signal value’ of a particular site found in an unrotated state of a wafer is used as it is for overlay error measurement in a 180-degree rotated state. However, as semiconductor devices become smaller and integrated, overlay marks become smaller, leading to a problem where an area illuminated by illumination used in the auto-focus device may become larger than a size of the overlay mark. If illumination exceeds the overlay mark and illuminates other nearby overlay marks or boundaries of a scribe line, there is a high likelihood that a signal from the auto-focus device is distorted. Furthermore, surrounding environments in the unrotated state and the 180-degree rotated state are different, so a tool-induced shift value measured by the conventional method may also be distorted. Therefore, if a measured overlay error value is corrected by applying a tool-induced shift value measured by the conventional method, an inaccurate overlay error value may be obtained.

FIGS. 4A-4B are views illustrating overlay marks and surrounding environments in an unrotated state and a 180-degree rotated state. FIG. 4A shows the unrotated state, and FIG. 4B shows the state in which the wafer is rotated by 180 degrees. As shown in FIGS. 4A-4B, lines (Ls) positioned above an overlay mark (OM) in the unrotated state are positioned below the overlay mark (OM) in the 180-degree rotated state. In addition, a laser beam (LB), which is illumination of the auto-focus device, illuminates nearby lines (Ls) beyond the overlay mark (OM). Accordingly, reflected light from the nearby lines (L) is also transmitted to the auto-focus device.

FIG. 5 is a graph illustrating distribution of difference values between overlay error values of respective sites of the same wafer measured by two different overlay measurement devices using the conventional method. FIG. 5 is illustrated based on a wafer in which each field has 25 sites. In the graph of FIG. 5, the X-axis represents a site index. The Y-axis represents a difference value between the overlay error values respectively obtained by the two devices. The distribution of Y values is the distribution among sites positioned in different fields having the same site index. An overlay error value used to illustrate FIG. 5 is not a general overlay error value, but a value obtained by subtracting an overlay error value in the 180-degree rotated state from an overlay error value in the unrotated state and then dividing the result by 2.

In FIG. 5, sites 2, 3, 7, 8, and 9 in the box are sites having a large difference in surrounding environments between the unrotated state and the 180-degree rotated state. As can be seen from FIG. 5, when the conventional method is used, the difference values of overlay error values of these sites exhibit distribution different from those of other sites. It can be said that accurate overlay error measurement is possible as a mean of the difference values of sites having the same site index is closer to 0, the dispersion of the difference values of sites having the same site index is smaller, and sites having different site indexes show distributions similar to each other.

### Documents of Related Art

(Patent Document 1) Japanese Patent Application Publication No. 2020-112807

(Patent Document 2) Korean Patent Application Publication No. 10-2001-0092740

(Patent Document 3) Korean Patent No. 10-2236184

(Patent Document 4) Korean Patent No. 10-2524462

(Patent Document 5) Korean Patent No. 10-1869573

### DISCLOSURE

### Technical Problem

The present disclosure is directed to providing an overlay measurement device capable of reducing distortion of tool-induced shift that occurs when an area illuminated by illumination used in an auto-focus device exceeds a size of an overlay mark.

In addition, the present disclosure is directed to providing a focus control method of an overlay measurement device for tool-induced shift measurement, and a focus control program of an overlay measurement device for tool-induced shift measurement.

### Technical Solution

According to the present disclosure, there is provided a focus control method of an overlay measurement device for tool-induced shift measurement, the focus control method including: obtaining, for each site of a reference field of a reference wafer in an unrotated state, a first signal that is a signal from an auto-focus device when the corresponding site is in focus; obtaining, for each site of the reference field after the reference wafer is rotated by 180 degrees, a second signal that is a signal from the auto-focus device when the corresponding site is in focus; matching the corresponding site with the first signal and the second signal for storage; positioning a measurement target site of a measurement target wafer within a field of view of the overlay measurement device; and adjusting a focus on the basis of the first signal matched with the measurement target site when the measurement target wafer is in an unrotated state, or adjusting a focus on the basis of the second signal matched with the measurement target site when the measurement target wafer is in a 180-degree rotated state.

In addition, in the focus control method of the overlay measurement device, the auto-focus device may be a phase difference detection auto-focus system, and the first signal and the second signal may be phase-difference-based signals.

In addition, in the focus control method of the overlay measurement device, the measurement target site may be a site of the reference field of the reference wafer or a field different from the reference field.

In addition, in the focus control method of the overlay measurement device, the measurement target wafer may be the reference wafer or another wafer belonging to the same lot as the reference wafer.

In addition, in the focus control method of the overlay measurement device, whether the measurement target wafer is rotated may be determined through a position of a flat zone or a notch of the wafer.

In addition, the first signal matched with the measurement target site may be the first signal obtained from the site within the reference field having the same in-field position as the measurement target site.

In addition, the present disclosure is directed to providing an overlay measurement device including: an objective lens; a lens focus actuator configured to adjust a distance between the objective lens and a wafer by moving the objective lens; an auto-focus device configured to output a signal according to the distance between the objective lens and the wafer; and a controller communicatively coupled to the lens focus actuator and the auto-focus device.

Herein, the controller includes a memory in which instructions are stored, and a processor configured to execute the instructions, and the instructions enable the processor to perform the following: obtaining, for each site of a reference field of a reference wafer in an unrotated state, a first signal that is a signal from the auto-focus device when the corresponding site is in focus; obtaining, for each site of the reference field after the reference wafer is rotated by 180 degrees, a second signal that is a signal from the auto-focus device when the corresponding site is in focus; matching the corresponding site with the first signal and the second signal for storage; positioning a measurement target site of a measurement target wafer within a field of view of the overlay measurement device; and adjusting a focus by moving the objective lens on the basis of the first signal matched with the measurement target site when the measurement target wafer is in an unrotated state, or adjusting a focus by moving the objective lens on the basis of the second signal matched with the measurement target site when the measurement target wafer is in a 180-degree rotated state.

In addition, the present disclosure is directed to providing a program for controlling a focus of an overlay measurement device, the program being stored in a storage medium to enable a method of controlling the focus of the overlay measurement device to be executed using a computing device, wherein the method includes: obtaining, for each site of a reference field of a reference wafer in an unrotated state, a first signal that is a signal from an auto-focus device when the corresponding site is in focus, wherein illumination of the auto-focus device is illumination extending spatially beyond an overlay mark formed at the site; obtaining, for each site of the reference field after the reference wafer is rotated by 180 degrees, a second signal that is a signal from the auto-focus device when the corresponding site is in focus, wherein illumination of the auto-focus device is illumination extending spatially beyond the overlay mark formed at the site; matching the corresponding site with the first signal and the second signal for storage; positioning a measurement target site of a measurement target wafer within a field of view of the overlay measurement device; and adjusting a focus on the basis of the first signal matched with the measurement target site when the measurement target wafer is in an unrotated state, or adjusting a focus on the basis of the second signal matched with the measurement target site when the measurement target wafer is in a 180-degree rotated state.

### Advantageous Effects

According to the present disclosure, distortion of tool-induced shift that occurs when an area illuminated by illumination used in the auto-focus device exceeds a size of an overlay mark can be reduced, and thus a more accurate tool-induced shift value can be obtained.

By correcting an overlay error using such a tool-induced shift value, an overlay error can be measured more accurately even on a wafer on which small-sized overlay marks are formed.

### DESCRIPTION OF DRAWINGS

FIG. 1 is a plan view of an example of an overlay mark.

FIG. 2 illustrates a signal obtained from one working zone of the overlay mark shown in FIG. 1.

FIG. 3 is a view illustrating an example of a wafer.

FIGS. 4A-4B are views illustrating overlay marks and surrounding environments in an unrotated state and a 180-degree rotated state.

FIG. 5 is a graph illustrating distribution of difference values between overlay error values of respective sites of the same wafer measured by two different overlay measurement devices using the conventional method.

FIG. 6 is a schematic view illustrating an overlay measurement device according to an embodiment of the present disclosure.

FIG. 7 is a flowchart illustrating a focus control method of an overlay measurement device for tool-induced shift measurement according to an embodiment of the present disclosure.

FIG. 8 illustrates an example of a table in which a first signal and a second signal are stored.

FIG. 9 is a graph illustrating distribution of difference values between overlay error values of respective sites of the same wafer measured by two different overlay measurement devices by applying a focus control method according to the present disclosure.

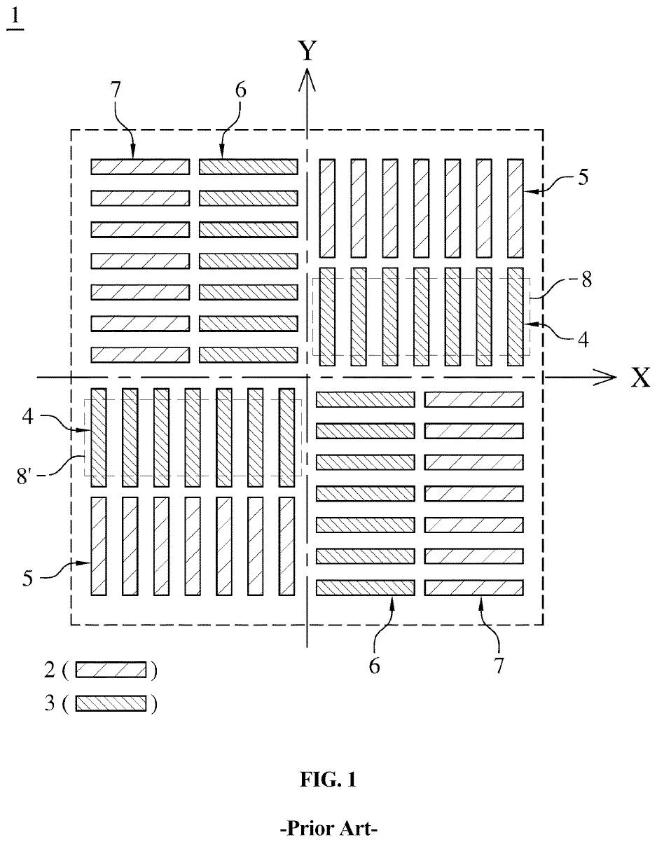

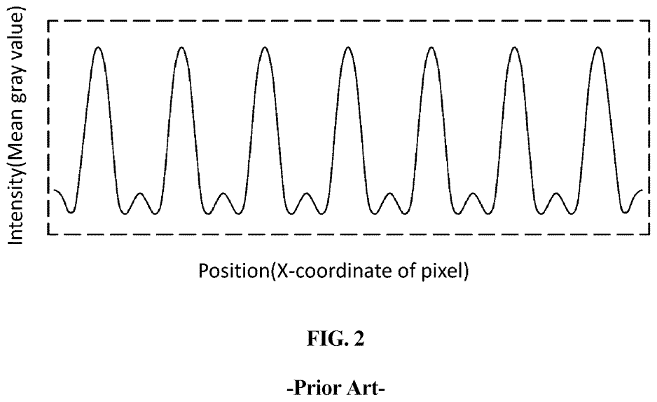

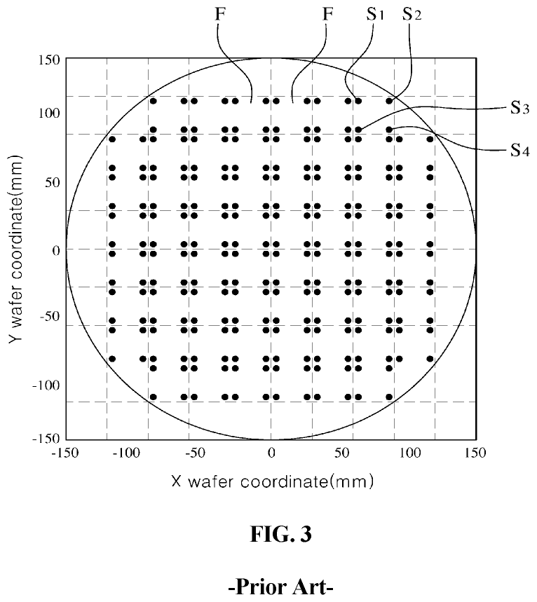

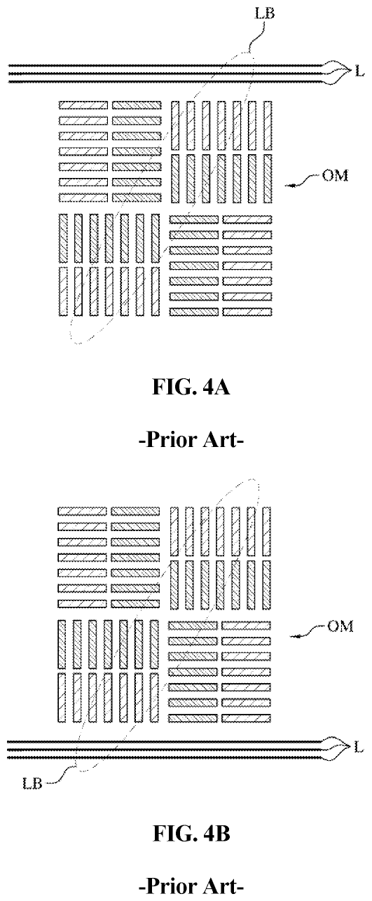

### MODE FOR INVENTION

Hereinafter, embodiments of the present disclosure will be described in detail with reference to the accompanying drawings. It should be understood that the embodiments of the present disclosure may be changed to a variety of embodiments and the scope of the present disclosure is not limited to the embodiments described hereinbelow. The embodiments of the present disclosure are provided in order to fully describe the disclosure for those of ordinary skill in the art. Therefore, shapes and sizes of the elements in the drawings may be exaggerated for a more precise description. Throughout the drawings, the elements denoted by the same reference numerals refer to the same elements.

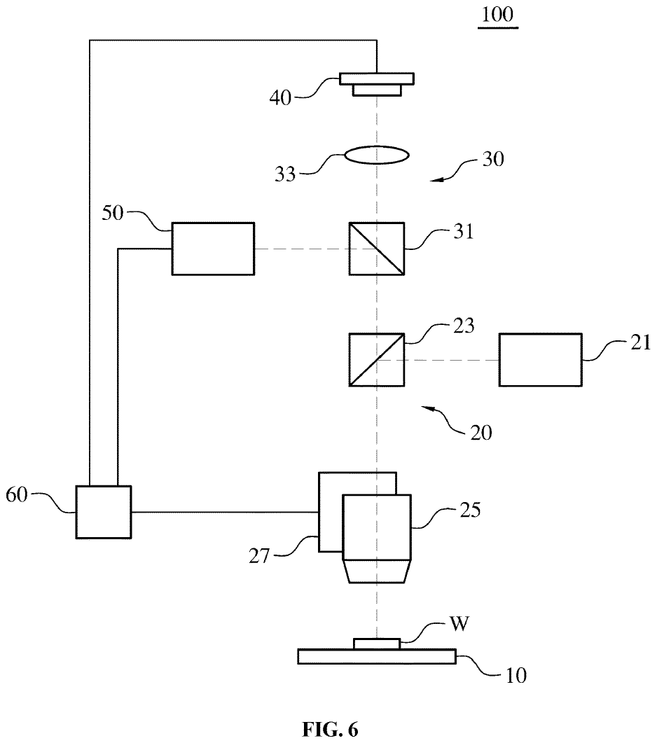

FIG. 6 is a schematic view illustrating an overlay measurement device according to an embodiment of the present disclosure. As shown in FIG. 6, an overlay measurement device 100 includes: a stage 10 for supporting a semiconductor wafer; an illumination optical system 20 for illuminating an overlay mark on the semiconductor wafer (W); an image-forming optical system 30 for concentrating reflected light from the overlay mark to form an overlay mark image; an image detector 40 for obtaining the overlay mark image formed by the image-forming optical system 30; an auto-focus device 50; and a controller 60.

The overlay measurement device 100 is used to measure an overlay error between a plurality of consecutive pattern layers.

The stage 10 is movable in X and Y directions, which are orthogonal to each other, by a horizontal driving part. The stage 10 supports the semiconductor wafer (W) and moves the same horizontally. The stage 10 may be provided with a vacuum chuck for fixing the semiconductor wafer (W).

The illumination optical system 20 may be configured using various optical elements. For example, the illumination optical system 20 may include an illumination source 21, a beam splitter 23, and an objective lens 25. In addition, other optical elements, such as lenses or diaphragms, may be further included.

The illumination source 21 generates illumination for illuminating the overlay mark. The illumination source 21 may include a light source for generating light of a wide wavelength band, and variable optical filters for adjusting the wavelength band of the transmitted light. As the light source, a laser diode or a light emitting diode may be used. The illumination source 21 may generate illumination in various wavelength bands by adjusting the wavelength band of light from the light source through combinations of the optical filters.

The beam splitter 23 is disposed between the illumination source 21 and the objective lens 25, and transfers illumination from the illumination source 21 to the objective lens 25.

The objective lens 25 concentrates illumination onto a measurement location on the surface of the semiconductor wafer (W), and collects the reflected light reflecting off the measurement location. The objective lens 25 is provided in a lens focus actuator 27. The lens focus actuator 27 is used to adjust the distance between the objective lens 25 and the semiconductor wafer (W). Focus control is performed by moving the objective lens 25 in a Z direction.

The image-forming optical system 30 may be configured using various optical elements. For example, the image-forming optical system 30 may include a hot or cold mirror 31 and a tube lens 33. In addition, the image-forming optical system 30 may use the objective lens 25 and the beam splitter 23 of the illumination optical system 20. In addition, other optical elements, such as lenses or diaphragms, may be further included.

The hot or cold mirror 31 prevents illumination used in the auto-focus device 50 from being directed toward the image detector 40. The hot mirror has high transmittance for short-wavelength light and reflects long-wavelength light. In contrast, the cold mirror has high transmittance for long-wavelength light and reflects short-wavelength light. When illumination used in the auto-focus device 50 has a shorter wavelength than illumination for obtaining images, the cold mirror is used to reflect the reflected light from illumination used in the auto-focus device 50 toward the auto-focus device 50. Conversely, when illumination used in the auto-focus device 50 has a longer wavelength than illumination for obtaining images, the hot mirror is used to reflect the reflected light from illumination used in the auto-focus device 50 toward the auto-focus device 50.

The reflected light collected by the objective lens 25 passes through the beam splitter 23 and is concentrated on the image detector 40 by the tube lens 33.

The image detector 40 receives the reflected light from the overlay mark due to illumination and generates an overlay mark image. The image detector 40 may be a charge-coupled device (CCD) camera or a complementary metal-oxide-semiconductor (CMOS) camera. The image detector 40 may use an imaging device provided with red, green, and blue (RGB) color filters, or may use a monochrome imaging device.

The auto-focus device 50 provides information on a Z-direction position of the surface of the wafer (w) required for focusing on a measurement target. The auto-focus device 50 provides a signal depending on the distance between the objective lens 25 and the surface of the wafer (w), for example. As the auto-focus device 50, various types of auto-focus systems may be used. For example, a phase difference detection auto-focus system, a contrast detection auto-focus system, or a hybrid auto-focus system may be used.

The phase difference detection auto-focus system may determine a direction and a distance in which the objective lens 25 is to be moved, by detecting a phase difference between light rays entering the overlay measurement device 100 from the wafer (w), which is a capturing target, using two or more sensors.

The contrast detection auto-focus system analyzes contrast between a bright area and a dark area of an image to determine a focus position. This system determines that the image is in focus when the contrast is maximized.

The hybrid auto-focus system obtains an approximate focus distance using a contrast detection method and then adjusts a focus position in full detail using a phase difference detection method.

The controller 60 is installed to be in wired or wireless communication with the lens focus actuator 27, the image detector 40, and the auto-focus device 50. The controller 60 may include hardware such as a processor, a memory, a read-only memory (ROM), a storage device, e.g., a hard disk or an SSD, and a wired or wireless communication device. In addition, included is a program such as firmware or software installed in a storage medium such as a memory, a ROM, or a storage device.

As the controller 60, a computing device, such as a micro controller unit (MCU), a desktop computer, a laptop computer, a smartphone, or a smart pad, may be used.

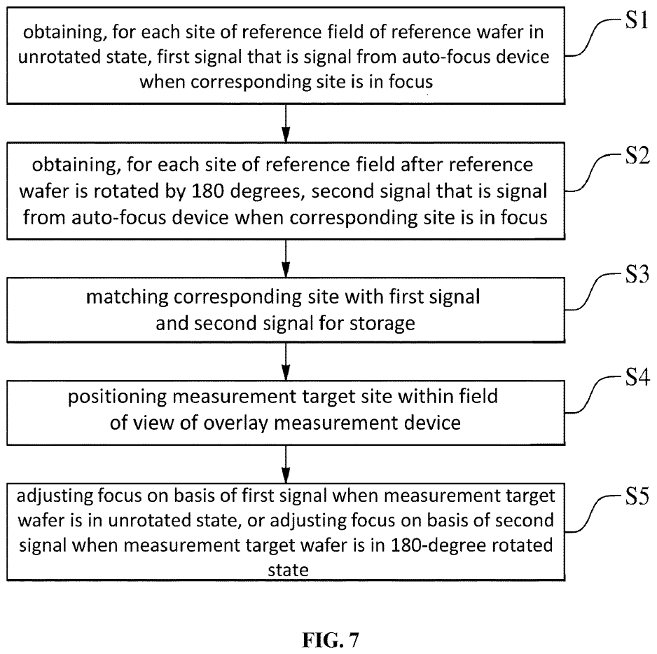

The controller 60 may enable the processor to perform the steps of FIG. 7 described below, through instructions of the program.

FIG. 7 is a flowchart illustrating a focus control method of an overlay measurement device for tool-induced shift measurement according to an embodiment of the present disclosure.

As shown in FIG. 7, the controller 60 performs a step (S1) of obtaining, for each site of a reference field of a reference wafer in an unrotated state, a first signal that is a signal from the auto-focus device when the corresponding site is in focus.

The reference wafer is one of a plurality of wafers belonging to the same lot. The reference wafer includes a plurality of fields. In one field, a plurality of sites exists (for example, 25 sites). An overlay mark is positioned at a site. The reference field is typically disposed at a center portion of a wafer.

In this step, for each site within the reference field, a first signal is obtained. The first signal is a signal of the auto-focus device 50 when the overlay mark of the corresponding site is in focus. In the case in which the phase difference detection auto-focus system is used as the auto-focus device 50, a phase value output from the phase difference detection auto-focus system when an overlay mark image is in ‘measurement focus’ may be the first signal. The measurement focus is a focus applied when an overlay mark image for actual overlay error measurement is obtained.

In a general imaging system, a focus found through the auto-focus device 50 is a ‘measurement focus’. However, an overlay mark includes overlay structures formed in conjunction with different pattern layers, so a ‘measurement focus’ may be positioned between an overlay structure formed on a previous pattern layer and an overlay structure formed on a current pattern layer. In particular, when the height difference between the overlay structures is large, the difference between the focus found through the auto-focus device 50 and the ‘measurement focus’ may be large. The ‘measurement focus’ may be found by evaluating the quality of the acquired overlay mark image using various quality metrics.

In the case in which the phase difference detection auto-focus system is used as the auto-focus device 50, while a general imaging system may consider an image to be in focus when a phase difference is 0, an overlay mark may be in focus (‘measurement focus’) even when the phase difference is not 0.

After obtaining a first signal from one site, the next site is positioned at the center of a field of view of the overlay measurement device 100 using a pattern recognition unit (PRU). Then, a first signal of the corresponding site is obtained in the same manner.

This process is repeated until first signals are obtained for all measurement target sites within the reference field. The first signals may vary from site to site depending on the types of the pattern layers on which overlay marks are formed, and height differences.

Next, the controller 60 performs a step (S2) of obtaining, for each site of the reference field after the reference wafer is rotated by 180 degrees, a second signal that is a signal from the auto-focus device 50 when the corresponding site is in focus.

In this step, first, the stage on which the reference wafer is seated is rotated by 180 degrees.

In addition, for each site within the reference field used in step S1, a second signal is obtained. The second signal is a signal of the auto-focus device 50 when the overlay mark of the corresponding site is in focus.

Ideally, the second signal regarding the overlay mark of the same site is identical to the first signal. In practice, however, the second signal may differ from the first signal. For example, when the size of a laser line, which is illumination used in the auto-focus device 50, is greater than the size of an overlay mark, a laser may be radiated beyond the overlay mark of a measurement target site onto nearby other overlay marks and patterns. Reflected light from these nearby marks or patterns may affect a signal of the auto-focus device 50. The degree of such influence may vary depending on a rotation angle of the wafer.

While the first and second signals for sites disposed at the center portion of the reference field may be similar, for sites such as upper or lower sites of the reference field where surrounding environments of the overlay marks change significantly depending on the rotation angle, the discrepancy between the first signal and the second signal may be very large.

This step is performed in the same manner as in step S1.

Next, the controller 60 performs a step (S3) of matching the corresponding site with the first signal and the second signal for storage.

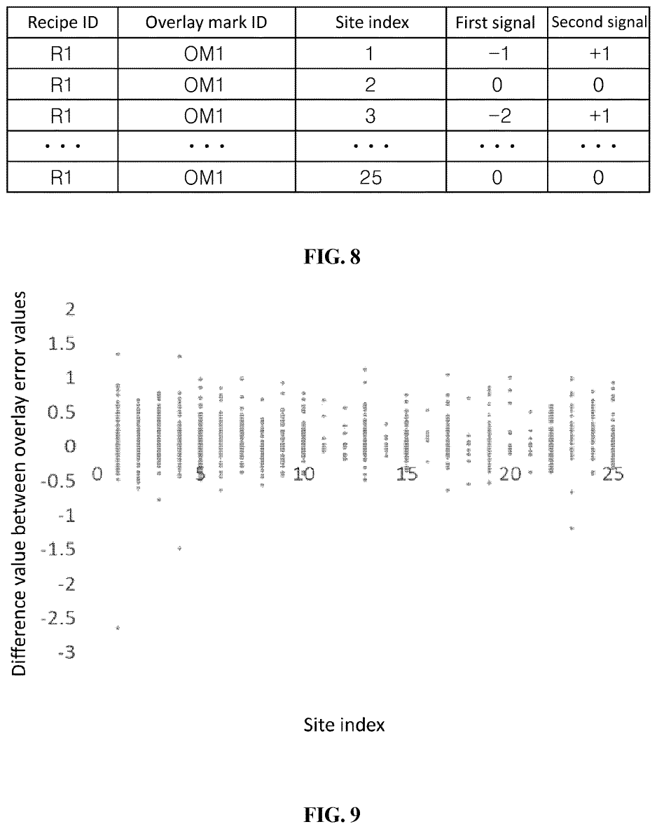

For example, as shown in FIG. 8, this may be stored in the memory of the controller 60 or other storage devices in the form of a table including a recipe ID, an overlay mark ID, a site index, a first signal, and a second signal. The first signals and the second signals of all sites within the reference field are stored in the table.

Next, the controller 60 performs a step (S4) of positioning a measurement target site of a measurement target wafer within a field of view of the overlay measurement device 100.

In this step, the controller 60 may move the wafer by moving the stage 10, which supports a measurement target wafer, in a planar manner. The measurement target wafer may be a reference wafer or another wafer belonging to the same lot as the reference wafer.

This step may include a global alignment step and a site alignment step. The controller 60 uses the pattern recognition unit to cause the overlay mark of the measurement target site to be positioned within the field of view of the overlay measurement device 100.

Measurement target sites may be sites of the reference field or other fields of the reference wafer used for obtaining the first signals and the second signals. In addition, the measurement target sites may be sites of fields of other wafers belonging to the same lot manufactured through the same process.

If sites have the same site index, the first signals and the second signals are substantially identical even for sites belonging to different fields of the same wafer or fields of different wafers of the same lot. Accordingly, information on the first signals and the second signals obtained from the reference field may be applied to sites of different fields of the same wafer and fields of different wafers of the same lot.

Next, the controller 60 may perform a step (S5) of adjusting a focus by moving the objective lens 25 on the basis of the first signal matched with the measurement target site when the measurement target wafer is in an unrotated state, or adjusting a focus by moving the objective lens on the basis of the second signal matched with the measurement target site when the measurement target wafer is in a 180-degree rotated state.

The controller 60 determines whether the measurement target wafer for which measurement of tool-induced shift is required is in an unrotated state or a 180-degree rotated state. The controller 60 may determine the rotation state of the measurement target wafer by determining a position of a flat zone or a notch of the measurement target wafer using a proximity sensor, for example.

When the measurement target wafer is in an unrotated state, the controller 60 adjusts a focus by moving the objective lens 25 using the first signal matched with the site having the same site index as the corresponding measurement target site stored in the table. When the measurement target wafer is in a 180-degree rotated state, a focus is adjusted by moving the objective lens 25 using the second signal stored in the table.

The controller 60 may adjust a focus by moving the objective lens 25 until a signal output from the auto-focus device 50 matches the first signal (or the second signal in the case of the 180-degree rotated state). The controller 60 may adjust the Z-axis direction position of the objective lens 25 by controlling the lens focus actuator 27.

Upon completion of the movement of the objective lens 25, the illumination optical system 20 is used to irradiate the measurement target site with illumination, and the reflected light from the overlay mark is concentrated on the image-forming optical system 30 to form an overlay mark image on the image detector 40, thereby obtaining an overlay mark image.

An X-direction overlay error and a Y-direction overlay error are measured using an overlay mark image obtained in the unrotated state. Subsequently, using an overlay mark image obtained for the same site in the 180-degree rotation state in the same manner, an X-direction overlay error and a Y-direction overlay error are measured again.

The X-direction tool-induced shift of the corresponding overlay mark (site) may be, for example, an average of the sum of the X-direction overlay error in the unrotated state and the X-direction overlay error in the 180-degree rotated state. In addition, the Y-direction tool-induced shift may be an average of the sum of the Y-direction overlay error in the unrotated state and the Y-direction overlay error in the 180-degree rotated state. Ideally, the X-direction tool-induced shift and the Y-direction tool-induced shift are 0.

The X-direction tool-induced shift and the Y-direction tool-induced shift may be used when an overlay error value measured at the corresponding site is corrected.

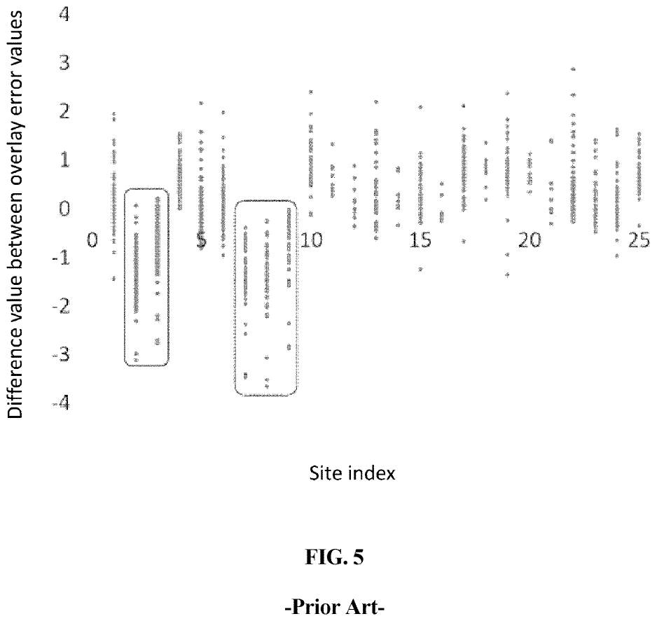

FIG. 9 is a graph illustrating distribution of difference values between overlay error values of respective sites of the same wafer measured by two different overlay measurement devices by applying a focus control method according to the present disclosure. In the graph of FIG. 9, the X-axis represents a site index, and the Y-axis represents a difference value in overlay error values between overlay measurement devices. Similarly to FIG. 5, shown is the distribution of overlay error values measured at the sites having the same site index of a plurality of fields of one wafer.

As shown in FIG. 9, when the focus control method according to the present disclosure is applied, the difference values of the overlay error values between sites having different site indexes show a similar distribution between the devices. That is, variations between sites caused by distortion due to illumination of the auto-focus device are reduced.

The embodiments described above are merely exemplary embodiments of the present disclosure, and the scope of the present disclosure is not limited to the above-described embodiments. Various changes, modifications, or substitutions may be made by those skilled in the art without departing from the technical idea of the present disclosure and claims. It should be understood that such embodiments fall within the scope of the present disclosure.

### DESCRIPTION OF THE REFERENCE NUMERALS IN THE DRAWINGS

w: wafer
10: stage
20: illumination optical system
30: image-forming optical system
40: image detector
50: auto-focus device
60: controller

1. A focus control method of an overlay measurement device for tool-induced shift measurement, the focus control method comprising:
obtaining, for each site of a reference field of a reference wafer in an unrotated state, a first signal that is a signal from an auto-focus device when the corresponding site is in focus, wherein illumination of the auto-focus device is illumination extending spatially beyond an overlay mark formed at the site;
obtaining, for each site of the reference field after the reference wafer is rotated by 180 degrees, a second signal that is a signal from the auto-focus device when the corresponding site is in focus, wherein illumination of the auto-focus device is illumination extending spatially beyond the overlay mark formed at the site;
matching the corresponding site with the first signal and the second signal for storage;
positioning a measurement target site of a measurement target wafer within a field of view of the overlay measurement device; and
adjusting a focus on the basis of the first signal matched with the measurement target site when the measurement target wafer is in an unrotated state, or adjusting a focus on the basis of the second signal matched with the measurement target site when the measurement target wafer is in a 180-degree rotated state.

2. The focus control method of claim 1, wherein the auto-focus device is a phase difference detection auto-focus system, and the first signal and the second signal are phase-difference-based signals.

3. The focus control method of claim 1, wherein the measurement target site is a site of the reference field of the reference wafer or a field different from the reference field.

4. The focus control method of claim 1, wherein the measurement target wafer is the reference wafer or another wafer belonging to the same lot as the reference wafer.

5. The focus control method of claim 1, wherein whether the measurement target wafer is rotated is determined through a position of a flat zone or a notch of the wafer.

6. The focus control method of claim 1, wherein the first signal matched with the measurement target site is the first signal obtained from the site within the reference field having the same in-field position as the measurement target site.

7. An overlay measurement device, comprising:
an objective lens;
a lens focus actuator configured to adjust a distance between the objective lens and a wafer by moving the objective lens;
an auto-focus device configured to output a signal according to the distance between the objective lens and the wafer; and
a controller communicatively coupled to the lens focus actuator and the auto-focus device, wherein the controller comprises a memory in which instructions are stored, and a processor configured to execute the instructions, and the instructions enable the processor to perform the following:
obtaining, for each site of a reference field of a reference wafer in an unrotated state, a first signal that is a signal from the auto-focus device when the corresponding site is in focus, wherein illumination of the auto-focus device is illumination extending spatially beyond an overlay mark formed at the site;
obtaining, for each site of the reference field after the reference wafer is rotated by 180 degrees, a second signal that is a signal from the auto-focus device when the corresponding site is in focus, wherein illumination of the auto-focus device is illumination extending spatially beyond the overlay mark formed at the site;
matching the corresponding site with the first signal and the second signal for storage;
positioning a measurement target site of a measurement target wafer within a field of view of the overlay measurement device; and
adjusting a focus by moving the objective lens on the basis of the first signal matched with the measurement target site when the measurement target wafer is in an unrotated state, or adjusting a focus by moving the objective lens on the basis of the second signal matched with the measurement target site when the measurement target wafer is in a 180-degree rotated state.

8. A program for controlling a focus of an overlay measurement device, the program being stored in a storage medium to enable a method of controlling the focus of the overlay measurement device to be executed using a computing device, wherein the method includes:
obtaining, for each site of a reference field of a reference wafer in an unrotated state, a first signal that is a signal from an auto-focus device when the corresponding site is in focus, wherein illumination of the auto-focus device is illumination extending spatially beyond an overlay mark formed at the site;
obtaining, for each site of the reference field after the reference wafer is rotated by 180 degrees, a second signal that is a signal from the auto-focus device when the corresponding site is in focus, wherein illumination of the auto-focus device is illumination extending spatially beyond the overlay mark formed at the site;
matching the corresponding site with the first signal and the second signal for storage;
positioning a measurement target site of a measurement target wafer within a field of view of the overlay measurement device; and
adjusting a focus on the basis of the first signal matched with the measurement target site when the measurement target wafer is in an unrotated state, or adjusting a focus on the basis of the second signal matched with the measurement target site when the measurement target wafer is in a 180-degree rotated state.
